(19) United States
(12) Patent Application Publication
(10) Pub. No.: US 2026/0215037 A1
(43) Pub. Date: Jul. 23, 2026

(54) NITRIDE SEMICONDUCTOR LIGHT-EMITTING ELEMENT

(71) Applicant: ASAHI KASEI KABUSHIKI KAISHA, Tokyo (JP)

(72) Inventor: Aya Yokoyama, Tokyo (JP)

(73) Assignee: ASAHI KASEI KABUSHIKI KAISHA, Tokyo (JP)

(21) Appl. No.: 19/141,618

(22) PCT Filed: Dec. 21, 2023
(86) PCT No.: PCT/JP2023/045975

§ 371 Date: Jun. 20, 2025

(30) Foreign Application Priority Data
Dec. 21, 2022 (JP) 2022-204799

(51) Int. Cl. H10H 20/825; H10H 20/821; H10H 20/831; H10H 20/857

(52) U.S. Cl. CPC H10H 20/825; H10H 20/821; H10H 20/831; H10H 20/857

(57) ABSTRACT

An object of this disclosure is to improve damage tolerance of a nitride semiconductor light-emitting element in external connection. A nitride semiconductor light-emitting element includes: a nitride semiconductor laminate including a light-emitting mesa structure placed on a first conductivity type semiconductor layer, and a protection mesa structure placed on the first conductivity type semiconductor layer and spatially separated from the light-emitting mesa structure to surround the light-emitting mesa structure; a first electrode placed on another part of the first conductivity type semiconductor layer and including electrode areas including a first electrode area placed away from the protection mesa structure via a first distance and a second electrode area placed away from the first electrode area via a second distance; a passivation layer covering respective surfaces of an edge of the protection mesa structure, outer edges of each of a plurality of electrode areas, and the first conductive semiconductor layer.

### TECHNICAL FIELD

This disclosure relates to a nitride semiconductor light-emitting element.

### BACKGROUND ART

In the related art, a nitride semiconductor element includes, for example: a substrate on which an n-type nitride semiconductor layer, a nitride semiconductor light-emitting layer, and a p-type nitride semiconductor light-emitting layer are laminated; an n-type electrode placed on an n-type nitride semiconductor layer; a p-type electrode placed on a p-type nitride semiconductor layer; and an external-connection pad electrode electrically connected to the n-type electrode and the p-type electrode (for example, PTL 1 and PTL 2).

### CITATION LIST

### Patent Literature

PTL 1: JP 2016-096193 A
PTL 2: WO 2016/163083 A1

In the case of such a nitride semiconductor element, a physical load may be applied to the element at the time when the nitride semiconductor element is externally connected to a package substrate, a wiring board, or the like, so that the nitride semiconductor element may be damaged. In the aforementioned nitride semiconductor element in the related art, for example, an external-connection electrode, a contact electrode, and a lead wire for electrically connecting the external-connection electrode to the contact electrode are formed separately to increase the thickness of a whole external connection electrode (PTL 1), or the n-type electrode right under the external-connection electrode is spatially separated so as to prevent spreading of corrosion of the n-type electrode (PTL 2), thereby restraining the damage to the nitride semiconductor element. However, from the viewpoint of damage tolerance, further improvement in restraining of the damage to the nitride semiconductor element has been required.

An object of this disclosure is to provide a nitride semiconductor element that is improved in damage tolerance in external connection.

In order to achieve the object, a nitride semiconductor light-emitting element according to one aspect of this disclosure includes: a substrate; a nitride semiconductor laminate including a first conductivity type semiconductor layer placed on the substrate, a light-emitting mesa structure placed on part of the first conductivity type semiconductor layer, and a protection mesa structure placed on the first conductivity type semiconductor layer and spatially separated from the light-emitting mesa structure to surround the light-emitting mesa structure, the protection mesa structure emitting no light; a first electrode placed on another part of the first conductivity type semiconductor layer and including at least two or more electrode areas including a first electrode area placed away from the protection mesa structure via a first distance in a plan view and a second electrode area placed away from the first electrode area via a second distance; a passivation layer directly covering respective surfaces of an edge of the protection mesa structure, outer edges of each of a plurality of electrode areas, and the first conductivity type semiconductor layer; and a first pad electrode placed to cover a surface of part of the passivation layer and a surface of at least part of an area of each of the plurality of electrode areas which area is not covered with the passivation layer, the first pad electrode being configured to electrically connect the plurality of electrode areas to each other.

Note that the summary of the invention does not describe all features of the invention according to this disclosure.

### Advantageous Effects of Invention

This disclosure can provide a nitride semiconductor element that is improved in damage tolerance in external connection.

### BRIEF DESCRIPTION OF DRAWINGS

FIG. 1 is a plan schematic view illustrating an exemplary structure of a nitride semiconductor light-emitting element according to a first embodiment of this disclosure;

FIG. 2A is a cross sectional schematic view illustrating an exemplary structure of the nitride semiconductor light-emitting element according to the first embodiment of this disclosure;

FIG. 2B is a cross sectional schematic view illustrating an exemplary structure of the nitride semiconductor light-emitting element according to the first embodiment of this disclosure;

FIG. 3 is a plan schematic view illustrating an exemplary structure of the nitride semiconductor light-emitting element according to the first embodiment of this disclosure;

FIG. 4 is an enlarged view illustrating part of an exemplary structure of the nitride semiconductor light-emitting element according to the first embodiment of this disclosure in an enlarged manner;

FIG. 5 is a plan schematic view illustrating an exemplary structure of a nitride semiconductor light-emitting element according to a comparative example of this disclosure;

FIG. 6 is a cross sectional schematic view illustrating an exemplary structure of the nitride semiconductor light-emitting element according to the comparative example of this disclosure;

FIG. 7 is a plan schematic view illustrating an exemplary structure of the nitride semiconductor light-emitting element according to the comparative example of this disclosure; and

FIG. 8 is a cross sectional schematic view illustrating an exemplary structure of the nitride semiconductor light-emitting element according to the comparative example of this disclosure.

### DESCRIPTION OF EMBODIMENTS

The following describes a nitride semiconductor light-emitting element according to this disclosure based on embodiments, but the following embodiments do not limit the invention according to Claims. In addition, all combinations of features described in the embodiments may not be essential to the solution of the invention.

Each drawing to be described in the following description is a schematic drawing, and a ratio of each dimension or thickness may not necessarily reflect an actual scale ratio. “Top” and “bottom” in the following description do not necessarily indicate a direction vertical to the ground. That is, directions of “top” and “bottom” are not limited to a gravitational direction. “Top” and “bottom” are only temporary expressions to identify a relative positional relationship in terms of surfaces, layers, a substrate, or the like and do not limit the technical idea of this disclosure. For example, it is needless to say that, when the plane of paper is rotated by 180 degrees, “top” becomes “bottom,” and “bottom” becomes “top.”

A nitride semiconductor light-emitting element according to an embodiment of this disclosure will be described.

### [Structure of Nitride Semiconductor Light-Emitting Element]

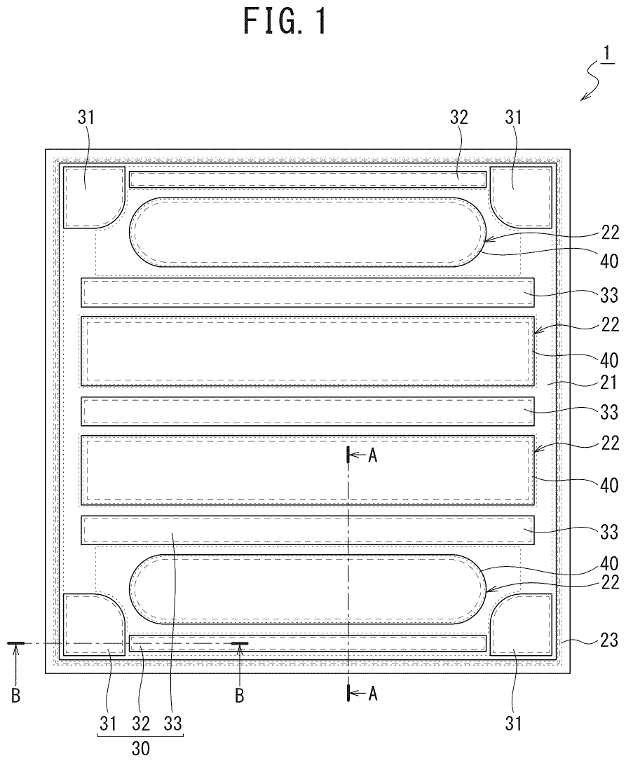

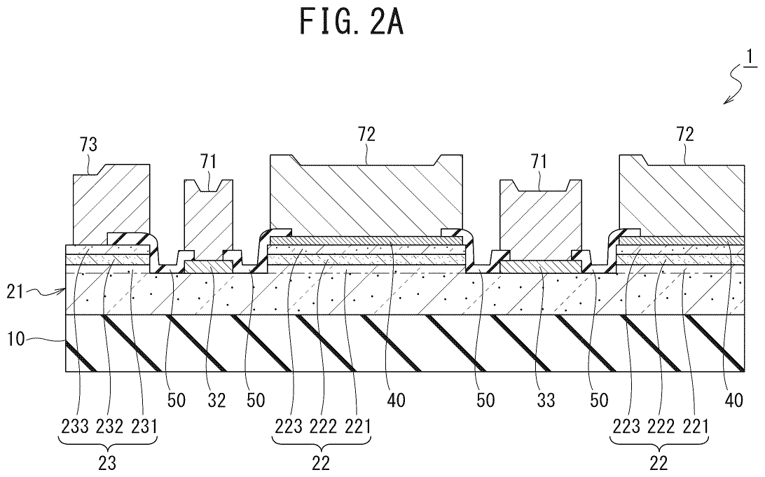

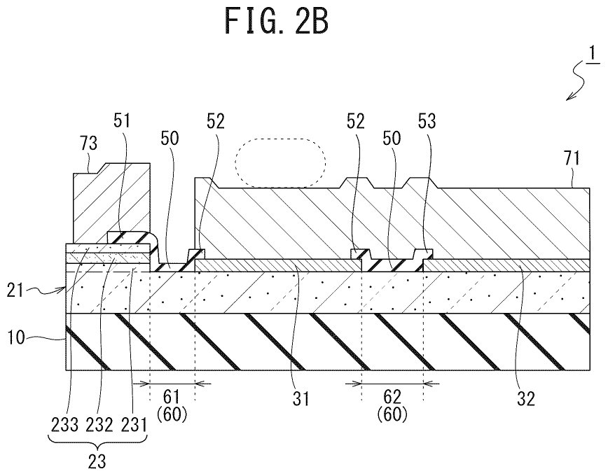

The following describes a specific exemplary structure of a nitride semiconductor light-emitting element 1 with reference to FIGS. 1 to 4. FIGS. 1 to 4 are schematic views to describe the nitride semiconductor light-emitting element 1 according to the present embodiment. FIG. 1 is a plan schematic view illustrating a planar structure of the nitride semiconductor light-emitting element 1. FIG. 2A is a cross sectional schematic view illustrating a sectional structure along a section A-A of the nitride semiconductor light-emitting element 1 illustrated in FIG. 1, and FIG. 2B is a cross sectional schematic view describing B-B cross section of the nitride semiconductor light-emitting element 1 illustrated in FIG. 1.

As illustrated in FIG. 1 and FIGS. 2A and 2B, the nitride semiconductor light-emitting element 1 according to one embodiment (hereinafter referred to as the present embodiment) of this disclosure includes a substrate 10, a nitride semiconductor laminate 20 placed on the substrate 10, a first electrode 30, a second electrode 40, a passivation layer 50, and a pad electrode 70. Here, in FIG. 1, an opening provided in the passivation layer 50 is indicated by a dashed line, and an area where the pad electrode 70 is formed is indicated by a dotted line. In FIG. 2B, an example of a position where a conductive bump is provided at the time when the nitride semiconductor light-emitting element 1 is externally connected is indicated by a dotted line.

As illustrated in FIG. 1 and FIG. 2A, the nitride semiconductor laminate 20 includes a first n-type semiconductor layer (an example of a first conductivity type semiconductor layer) 21, a light-emitting mesa structure 22 placed on part of the first n-type semiconductor layer 21, and a protection mesa structure 23 placed on the first n-type semiconductor layer 21 and specially separated from the light-emitting mesa structure 22. The light-emitting mesa structure 22 includes a light-emitting layer. The protection mesa structure 23 has a function to protect an area inward of the protection mesa structure 23 which area includes the light-emitting mesa structure 22. It is preferable that the protection mesa structure 23 be placed on an outer edge of the substrate.

The first electrode 30 is placed on the other part (an area not provided with the light-emitting mesa structure 22) of the first n-type semiconductor layer 21. As illustrated in FIGS. 2A, 2B, the first electrode 30 includes a first electrode area 31 as a base of an external connection portion, and a second electrode area 32 placed to be spatially separated from the first electrode area 31. The first electrode area 31 is placed away from the protection mesa structure 23 via a first narrow space 61. The second electrode area 32 is placed away from the first electrode area 31 via a second narrow space 62. That is, the first narrow space 61 is formed by spatial arrangement of the protection mesa structure 23 and the first electrode area 31, and the second narrow space 62 is formed by spatial arrangement of the first electrode area 31 and the second electrode area 32. Hereinafter, in a case where the first narrow space 61 and the second narrow space 62 are not distinguished from each other, they may be referred to as a narrow space 60.

The first electrode 30 also includes a third electrode area 33 placed between the light-emitting mesa structures 22. Part of the third electrode area 33 is placed at a position facing the second electrode area 32 via the light-emitting mesa structure 22.

The second electrode 40 is placed on the light-emitting mesa structure 22.

The pad electrode 70 includes a first pad electrode portion 71 and a second pad electrode portion 72.

The first pad electrode portion 71 is placed to cover the surface of part of the passivation layer 50, and the surface of the first electrode 30 (the first electrode area 31, the second electrode area 32, and the third electrode area 33) not covered with the passivation layer 50. More specifically, the first pad electrode portion 71 is provided to cover part of a second passivation covering area 52 and a third passivation covering area 53 (described later in detail). Further, the first pad electrode portion 71 electrically connects the first electrode area 31, the second electrode area 32, and the third electrode area 33 to each other.

The second pad electrode portion 72 is placed on part of the passivation layer 50 and the second electrode 40 not covered with the passivation layer 50.

More preferably, the pad electrode 70 includes a third pad electrode portion 73 covering the surface of part of the passivation layer 50, and part of the protection mesa structure 23 not covered with the passivation layer 50. More specifically, the third pad electrode portion 73 is provided to cover at least part of the first passivation covering area 51.

The narrow space 60 includes the first narrow space 61 formed by spatial arrangement of the protection mesa structure 23 and the first electrode area 31, and the second narrow space 62 formed by spatial arrangement of the first electrode area 31 and the second electrode area 32.

The passivation layer 50 is formed over the whole surface of the nitride semiconductor light-emitting element 1 except an outer peripheral portion of the protection mesa structure 23 (an outer peripheral portion of the nitride semiconductor light-emitting element 1), a central portion of the first electrode 30 (the first electrode area 31, the second electrode area 32, and the third electrode area 33), and a central portion of the second electrode 40 and is also formed over the first narrow space 61 and the second narrow space 62. The passivation layer 50 includes a first passivation covering area 51 covering an outer edge of the protection mesa structure 23 which outer edge faces the first electrode area 31, a second passivation covering area 52 covering an outer edge of the first electrode area 31, and a third passivation covering area 53 covering an outer edge of the second electrode area 32. That is, the first passivation covering area 51 covers an end portion on the top surface of the protection mesa structure 23 and a lateral surface thereof, the second passivation covering area 52 covers an end portion on the top surface of the first electrode area 31 and a lateral surface thereof, and the third passivation covering area 53 covers an end portion on the top surface of the second electrode area 32 and a lateral surface thereof.

Since the nitride semiconductor light-emitting element 1 according to the present embodiment has the above-mentioned structure, it is possible to improve damage tolerance in external connection. The damage in external connection means, for example, peeling of a conductive-bump provided area from the pad electrode 70 or a lower layer of the first electrode 30, breakage of the conductive-bump provided area, peeling of the passivation layer 50, and cracks (including microcracks) of the passivation layer 50. When the nitride semiconductor light-emitting element 1 is damaged, the nitride semiconductor light-emitting element 1 deteriorates during current application particularly under a high humidity environment. The deterioration of the nitride semiconductor light-emitting element 1 during current application mainly indicates an increase in forward voltage or open mode failure due to corrosion of an electrode or corrosion of a semiconductor layer. In a case of an AlGaN-based nitride semiconductor light-emitting element, the semiconductor layer easily corrodes as the composition of Al is higher. Besides, when peeling of the pad electrode 70 or the first electrode 30 occurs, a risk that the nitride semiconductor light-emitting element 1 falls off from a package substrate, a wiring board, or the like (not illustrated) to which the nitride semiconductor light-emitting element 1 is externally connected increases.

When the nitride semiconductor light-emitting element 1 includes the passivation layer 50 formed over the narrow space 60, the adhesion of the passivation layer 50 improves due to anchor effect. Hereby, an effect of holding down the first electrode area 31 increases, thereby improving the adhesion of the first electrode area 31 to a lower layer (the first n-type semiconductor layer 21) below the first electrode area 31.

Accordingly, the nitride semiconductor light-emitting element 1 including the passivation covering area and the narrow space 60 does not cause peeling of the pad electrode 70 or the first electrode 30 in external connection, and thus, the nitride semiconductor light-emitting element 1 is markedly excellent in damage tolerance.

In the meantime, the first pad electrode portion 71 of the present embodiment also functions as a lead-out electrode that electrically connects the first electrode area 31 to the second electrode area 32. The first pad electrode portion 71 also functions as a lead-out electrode that electrically connects the first electrode area 31 and the second electrode area 32 to the third electrode area 33. Accordingly, a step of separately forming an external connection portion and a lead-out electrode is not necessary, which is also preferable from the viewpoint of simplification of a manufacturing process.

Besides, the narrow space 60 can be formed by spatial arrangement of the protection mesa structure 23 and the first electrode area 31, and spatial arrangement of the first electrode area 31 and the second electrode area 32. This is also preferable from the viewpoint that the nitride semiconductor light-emitting element 1 having a high damage tolerance can be achieved without changing the manufacturing process.

In addition, in the present embodiment, the damage tolerance can improve, and therefore, it is not necessary to design the nitride semiconductor light-emitting element 1 with a large margin secured for the size of the external connection portion or positional deviation. This is also preferable from the viewpoint that it is possible to reduce an area not contributing to light emission the nitride semiconductor light-emitting element 1 and to increase output power per unit area of a chip.

Besides, the second narrow space 62 has an effect of restraining the spread of corrosion to the second electrode area 32 even when the first electrode area 31 corrodes during current application under a high humidity environment, for example. In this case, the corrosion does not spread through the second electrode area 32 and disturb the supply of carriers to the light-emitting mesa structure 22, so that a decrease in element performance such as an increase in forward voltage, open mode failure, or deterioration of light-emission performance during current application does not occur. In view of this, the nitride semiconductor light-emitting element 1 including the second narrow space 62 may be also preferable from the viewpoint that a decrease in element performance is further restrained during current application under a high humidity environment.

Next will be described details of each constituent of the nitride semiconductor light-emitting element 1 according to the present embodiment.

### <Substrate>

The substrate 10 is not limited particularly, provided that the first n-type semiconductor layer 21 can be formed on the substrate 10. More specifically, the substrate 10 is made of, for example, sapphire, Si, SiC, MgO, Ga2O3, ZnO, GaN, InN, AlN, a mixed crystal substrate thereof, or the like.

It is preferable that the substrate 10 be a single crystalline substrate with a nitride semiconductor such as GaN, AlN, or AlGaN being taken as bulk or a nitride semiconductor layer (also referred to as a template) such as GaN, AlN, or AlGaN grown on a given material, from the viewpoint that a lattice constant difference between the substrate 10 and the first n-type semiconductor layer 21 formed on the substrate 10 is small, and threading dislocation can be reduced by lattice matched growth, or from the viewpoint that lattice distortion for hole gas generation can be increased. An impurity may be mixed in the substrate 10.

From the viewpoint of improvement in extraction of light, a surface of the substrate 10 which surface is opposite to a surface on which the first n-type semiconductor layer 21 is formed may be processed.

### <Nitride Semiconductor Laminate>

The nitride semiconductor laminate 20 includes the first n-type semiconductor layer 21, the light-emitting mesa structure 22 placed on the first n-type semiconductor layer 21, and the protection mesa structure 23.

The light-emitting mesa structure 22 and the protection mesa structure 23 have a mesa structure projecting from part of the first n-type semiconductor layer 21. A method for forming the mesa structure is not limited particularly, but the mesa structure can be formed in such a manner that each layer is laminated on the substrate 10 with the use of a well-known film deposition apparatus using a method such as a molecular beam epitaxy (MBE) method or a metal organic chemical vapor phase deposition (MOCVD) method, a mask pattern is formed by a photolithography method, and a desired area is etched by dry etching or wet etching.

The light-emitting mesa structure 22 and the protection mesa structure 23 are spatially separated from each other. Here, “spatially separated” indicates that a lateral surface of the light-emitting mesa structure 22 and a lateral surface of the protection mesa structure 23 are present but are not in contact with each other.

In order that the nitride semiconductor light-emitting element 1 has a longer life, it is preferable that the protection mesa structure 23 be placed to surround the light-emitting mesa structure 22 in a plan view. Here, “placed to surround” indicates that 50% or more of sides of a minimum projecting polygonal shape surrounding all the light-emitting mesa structures 22 in a plan view face the lateral surface of the protection mesa structure 23.

The light-emitting mesa structure 22 includes a second n-type semiconductor layer (an example of a first conductivity type semiconductor layer) 221, a first quantum well layer 222 placed on the second n-type semiconductor layer, and a first p-type semiconductor layer 223 placed on the first quantum well layer 222.

The protection mesa structure 23 includes a third n-type semiconductor layer 231, a second quantum well layer 232 placed on the third n-type semiconductor layer, and a second p-type semiconductor layer 233 placed on the second quantum well layer 232.

In a plan view, it is preferable that an end portion of part of the protection mesa structure 23 overlap with an end portion of part of the substrate 10, that is, the lateral surface of the protection mesa structure 23 be placed on generally the same surface as the lateral surface of the substrate 10. Hereby, for example, the protection mesa structure 23 can cover the first n-type semiconductor layer 21 as well as a chip outer peripheral portion, thereby making it possible to protect a large area on the first n-type semiconductor layer 21. For example, in a case where the Al composition ratio of the first n-type semiconductor layer 21 is high, the first n-type semiconductor layer 21 tends to easily deteriorate. However, when the protection mesa structure 23 is provided on the first n-type semiconductor layer 21, it is possible to reduce an exposed area of the first n-type semiconductor layer 21. Hereby, it is possible to restrain deterioration of the first n-type semiconductor layer 21 and to achieve the nitride semiconductor light-emitting element 1 having a longer life. Note that, “overlap” indicates that a deviation between part of the end portion of the protection mesa structure 23 and the end portion of the substrate 10 is equal to or less than 2 μm in a plan view.

<n-Type Semiconductor Layer>

The n-type semiconductor layer (an example of a first conductivity type semiconductor layer) includes the first n-type semiconductor layer 21, the second n-type semiconductor layer 221 as part of the light-emitting mesa structure 22, and the third n-type semiconductor layer 231 as part of the protection mesa structure 23.

As illustrated in FIG. 2A and so on, the first n-type semiconductor layer 21 is directly formed on the substrate 10. Alternatively, a layer other than the first n-type semiconductor layer 21 may be provided on the substrate 10, and the first n-type semiconductor layer 21 may be provided on the layer other than the first n-type semiconductor layer 21. More specifically, for example, a buffer layer (not illustrated) may be provided on the substrate 10, and the first n-type semiconductor layer 21 may be provided on the buffer layer.

The first n-type semiconductor layer 21, the second n-type semiconductor layer 221, and the third n-type semiconductor layer 231 are preferably made of AlₓGa₁₋ₓN (x>0.3) and more preferably made of n-type AlₓGa₁₋ₓN (x>0.3). This improves light-emission efficiency of the nitride semiconductor light-emitting element 1.

The first n-type semiconductor layer 21, the second n-type semiconductor layer 221, and the third n-type semiconductor layer 231 may contain V group elements such as P, As, and Sb other than the n-type dopant or impurities such as C, H, F, O, Mg, and Si.

### <Quantum Well Layer>

The quantum well layer includes the first quantum well layer 222 as part of the light-emitting mesa structure 22, and the second quantum well layer 232 as part of the protection mesa structure 23.

As illustrated in FIG. 2A, the first quantum well layer 222 is directly provided on the second n-type semiconductor layer 221, and the second quantum well layer 232 is directly provided on the third n-type semiconductor layer 231. Alternatively, the first quantum well layer 222 may be provided on a layer other than a quantum well layer which layer is provided on the second n-type semiconductor layer 221. More specifically, an AlGaN layer (not illustrated) doped with no impurity may be provided on the second n-type semiconductor layer 221, and the first quantum well layer 222 may be provided on the AlGaN layer. Similarly, the second quantum well layer 232 may be provided on an AlGaN layer (not illustrated) doped with no impurity, or the like, that is formed on the third n-type semiconductor layer 231.

The first quantum well layer 222 and the second quantum well layer 232 are not limited particularly, provided that they are nitride semiconductor layers.

However, it is desirable that the first quantum well layer 222 and the second quantum well layer 232 be mixed crystals of AlN, GaN, and InN from the viewpoint that a high light-emission efficiency is achieved. The first quantum well layer 222 and the second quantum well layer 232 may also contain V group elements such as P, As, and Sb other than N or impurities such as C, H, F, O, Mg, and Si. The first quantum well layer 222 and the second quantum well layer 232 may have a multi-quantum-well structure or a single-layered quantum well structure, but it is desirable that the first quantum well layer 222 and the second quantum well layer 232 have at least two or more well structures from the viewpoint that a high light-emission efficiency is achieved.

<p-Type Semiconductor Layer>

The p-type semiconductor layer includes the first p-type semiconductor layer 223 as part of the light-emitting mesa structure 22, and the second p-type semiconductor layer 233 as part of the protection mesa structure 23. The p-type semiconductor layer corresponds to a second conductivity type semiconductor layer.

As illustrated in FIG. 2A, the first p-type semiconductor layer 223 is directly formed on the first quantum well layer 222, and the second p-type semiconductor layer 233 is directly formed on the second quantum well layer 232. Alternatively, the first p-type semiconductor layer 223 may be provided on a layer other than a p-type semiconductor layer provided on the second n-type semiconductor layer 221. More specifically, a composition graded layer (not illustrated) in which the ratio between constituent composition changes continuously or discretely may be provided on the first quantum well layer 222, and the first p-type semiconductor layer 223 may be provided on the composition graded layer. Similarly, the second p-type semiconductor layer 233 may be provided on a composition graded layer or the like provided on the second quantum well layer 232.

A barrier layer having a relatively large band gap may be further provided between the composition graded layer and the first p-type semiconductor layer 223 or the second p-type semiconductor layer 233.

It is preferable that the proportion of Al elements in constituent elements of the uppermost surfaces of the first p-type semiconductor layer 223 and the second p-type semiconductor layer 233 be larger because light having a wavelength of a deep-ultraviolet region is easily transmitted, and a high light-emission efficiency can be achieved. However, when the proportion of Al elements is too large, a chemical reaction with oxygen or moisture in air is easily promoted, so that deterioration easily occurs. In view of this, in order to achieve the nitride semiconductor light-emitting element 1, it is preferable that the first p-type semiconductor layer 223 and the second p-type semiconductor layer 233 be made of Al_{y}Ga_{1-y}N (0≤y≤0.6).

From the viewpoint of efficiently generating two-dimensional hole gas in the composition graded layer and the p-type semiconductor layer, it is preferable that the p-type semiconductor layer be warped, that is, its relaxation rate be decreased. In order to decrease the relaxation rate of the p-type semiconductor layer, the p-type semiconductor layer preferably has a thickness of 1 nm to 10 nm, more preferably a thickness of 4 nm to 8 nm.

An electrode may make direct contact with an upper layer of the p-type semiconductor layer, or an electrode may make contact with an uppermost surface of a plurality of laminated p-type semiconductor layers. The p-type semiconductor layer may contain a p-type dopant from the viewpoint of generating holes inside a thin film or may not contain a dopant for holes being directly injected into two-dimensional hole gas on an interface from the electrode. Mg is generally used as the p-type dopant, but Be, Zn, and the like are also usable, provided that they are impurities that generate holes.

As a method for identifying a composition difference between the p-type semiconductor layer and an outermost surface of the composition graded layer, various analytical methods such as XRD (X-ray diffraction), EDX (energy dispersive X-ray spectroscopy), XRF (fluorescent X-ray spectrographic analysis), AES (Auger electron spectroscopy), SIMS (secondary ion mass spectrometry), and EELS (electron energy loss spectroscopy) can be used.

### <First Electrode>

The first electrode 30 includes a first electrode area 31 formed on the top surface of the first n-type semiconductor layer 21 and serving as a base of the external connection portion, and a second electrode area 32 formed on the top surface of the first n-type semiconductor layer 21 and spatially separated from the first electrode area 31. The first electrode 30 further includes a third electrode area 33 placed on the first n-type semiconductor layer 21 and facing the second electrode area 32 via the light-emitting mesa structure 22. Here, “spatially separated” indicates that a lateral surface of the first electrode area 31 and a lateral surface of the second electrode area 32 are present and are not in contact with each other. The first electrode area 31 is provided to increase the adhesion of the base of the external connection portion, and the second electrode area 32 and the third electrode area 33 are provided to supply electron to the light-emitting mesa structure 22.

From the viewpoint of reliability for falling of the external connection portion or the like, for example, it is preferable that the number of first electrode areas 31 be large. However, when the number of first electrode areas 31 is too large, an area ratio of the light-emitting mesa structure 22 is small, and a relative output power per unit area decreases, which is unfavorable. On this account, when the first electrode area 31 is formed preferably in two or more corners of the substrate 10, more preferably in four corners of the substrate 10, it is possible to improve the reliability of the external connection portion and to efficiently increase adhesion without decreasing the area ratio of the light-emitting mesa structure 22.

The first electrode 30 has effects such as improvement in adhesion of an electrode and prevention of oxidation of an electrode material and is formed with the use of a material that decreases a contact resistance to the first n-type semiconductor layer 21. Such a material may be, for example, metals such as Ti, Al, Ni, Mo, V, Au, W, Pt, Pd, Si, Zr, Cr, Hf, Nb, Ta, Co, Rh, Ir, Cu, and Ag, alloys containing them, a conductive oxide such as ITO or Ga2O3, and the like. More preferably, the first electrode 30 is made of a material containing titanium, aluminum, Ni, and gold but is not limited to these materials.

In a case where the first electrode 30 is made of titanium, aluminum, Ni, and gold, it is preferable that the first electrode 30 include an alloy layer containing aluminum and Ni and formed on a contact surface to the first n-type semiconductor layer 21 or in the vicinity of the contact surface, and an aluminum-containing layer other than the alloy layer. Here, the vicinity of the contact surface indicates a portion near the first n-type semiconductor layer 21 of the first electrode 30 but not in contact with the first n-type semiconductor layer 21, and an area between the contact surface and a position distanced from the contact surface by 3 nm within a layer of the first electrode 30, for example.

In order to decrease the resistance of an interface between the first electrode 30 and the first n-type semiconductor layer 21, at least part of the contact surface of the first electrode 30 may contain, for example, Ti, Mo, V, Au, W, Pt, Pd, Si, Zr, or the like. The at least part of the contact surface of the first electrode 30 may contain more preferably Ti or Au, further more preferably Ti.

In the first electrode 30, the alloy layer containing aluminum and Ni and the aluminum-containing layer may be separately provided in a plurality of areas. In this case, in the first electrode 30, a total presence ratio of the alloy layer containing aluminum and Ni and the aluminum-containing layer is preferably equal to or more than 60%, and more preferably equal to or more than 70%. However, the first electrode 30 is not limited to these structures.

Such a first electrode 30 can be formed in such a manner that a metal laminate is deposited by sputtering or vapor deposition, for example, on the first n-type semiconductor layer 21 and subjected to heat-treating by RTA (Rapid Thermal Annealing) or the like, for example. The first electrode area 31, the second electrode area 32, and the third electrode area 33 of the first electrode 30 can be formed at the same time by one lithography, film formation, or heat treatment, which is preferable from the viewpoint of simplification of the manufacturing process.

### <Second Electrode>

The second electrode 40 is provided to supply electron holes (holes) to the nitride semiconductor light-emitting element 1. The second electrode 40 is formed on the top surface of the first p-type semiconductor layer 223 of the light-emitting mesa structure 22.

The second electrode 40 should be made of a conductive material. Such a material can be, for example, Ni, Al, Ti, Au, Pt, Ag, Rh, Pd, Pt, Cu, alloys thereof, ITO, and the like. More preferably, Ni or Au having a small contact resistance to the nitride semiconductor layer, or an alloy layer thereof is used. Such an electrode can be formed in such a manner that a metal laminate is deposited by sputtering or vapor deposition, for example, and subjected to heat-treating by RTA (Rapid Thermal Annealing) or the like, for example.

Each electrode may also contain an UV (ultraviolet) reflector. The UV reflector has a structure to prevent photons from leaving from a semiconductor layer structure by directing again the photons emitted toward the electrode. The UV reflector is also designed to improve the extraction efficiency of photons generated in an active region of a device by directing again the photons toward a desired light-emitting surface, e.g., a bottom surface.

### <Arrangement of Protection Mesa Structure, First Electrode Area, and Second Electrode Area>

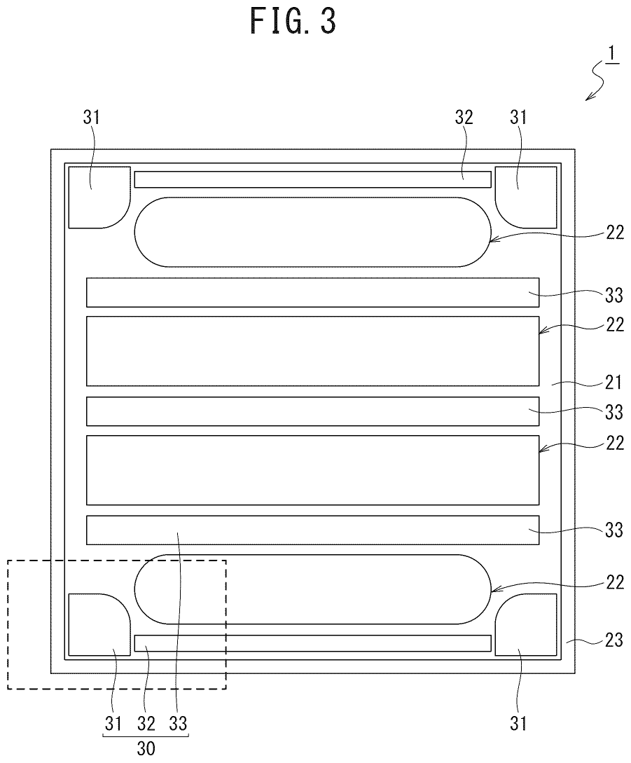

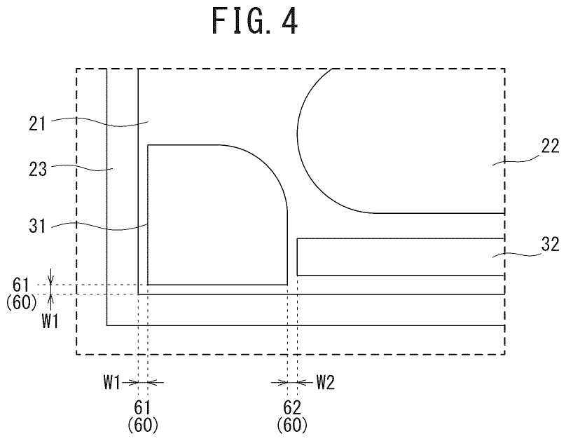

The narrow space 60 formed between the protection mesa structure 23 and the first electrode area 31 and between the first electrode area 31 and the second electrode area 32 will be described with reference to FIGS. 3, 4. FIG. 3 is a plan schematic view illustrating an exemplary structure of the nitride semiconductor light-emitting element 1 and illustrates the light-emitting mesa structure 22, the protection mesa structure 23, the first electrode 30 (the first electrode area 31, the second electrode area 32, the third electrode area 33), and the first n-type semiconductor layer 21. FIG. 4 is an enlarged view illustrating an area indicated by a broken line in FIG. 3 in an enlarged manner.

Before the passivation layer 50 is formed, the narrow space 60 having a predetermined distance is formed between the protection mesa structure 23 and the first electrode area 31. Before the passivation layer 50 is formed, the narrow space 60 includes the first narrow space 61 formed by spatial arrangement of the protection mesa structure 23 and the first electrode area 31 provided via a first distance W1. In the meantime, the narrow space 60 includes the second narrow space 62 formed by spatial arrangement of the first electrode area 31 and the second electrode area 32 provided via a second distance W2. It is preferable that the protection mesa structure 23 be placed on an outer edge of the substrate 10. Accordingly, the first electrode area 31 is provided for two or more corners of the substrate 10, more preferably four corners thereof in a plan view, and the first electrode area 31 is preferably placed away from the protection mesa structure 23 via the first distance W1. As illustrated in FIG. 4, the light-emitting mesa structure 22 and the protection mesa structure 23 are placed in an area other than the first narrow space 61 and the second narrow space 62.

When the passivation layer 50 is formed over the first narrow space 61 and the second narrow space 62 (details will be described later), the adhesion of the passivation layer 50 around the first electrode area 31 improves due to anchor effect.

The first narrow space 61 is formed in an area surrounded by the lateral surface of the protection mesa structure 23 and the lateral surface of the first electrode area 31. As illustrated in FIG. 4, the first narrow space 61 is formed to preferably surround at least two sides of each first electrode area 31, and the number of first narrow spaces 61 is preferably the same as the number of first electrode areas 31. In the meantime, the first narrow space 61 is preferably formed in two or more corners of the nitride semiconductor light-emitting element 1, more preferably four corners of the nitride semiconductor light-emitting element 1. However, the first narrow space 61 is not limited to these structures.

The first distance W1 (see FIG. 4) that is a width of the first narrow space 61 is determined by a distance between the protection mesa structure 23 and the first electrode area 31. When the first distance W1 is too small, the passivation layer 50 cannot sufficiently cover the first narrow space 61, or the first narrow space 61 may not be formed due to misalignment in the manufacturing process. In the meantime, when the first distance W1 is too large, the ratio of a chip area to an area of a light emitting portion increases, and an area that do not contribute to light emission increases. Accordingly, the first distance W1 is preferably equal to or more than 0.5 μm but equal to or less than 25 μm, more preferably equal to or more than 1 μm but equal to or less than 20 μm.

The second narrow space 62 is formed by an area surrounded by the lateral surface of the first electrode area 31 and the lateral surface of the second electrode area 32. As illustrated in FIG. 4, the second narrow space 62 is preferably formed between each of the first electrode areas 31 and its closest second electrode area 32, and the number of second narrow spaces 62 is preferably the same as the number of first electrode areas 31. However, the second narrow space 62 is not limited to these structures.

The second distance W2 (see FIG. 4) that is the width of the second narrow space 62 is determined by a distance between the first electrode area 31 and the second electrode area 32. When the second distance W2 is too small, the passivation layer 50 cannot sufficiently cover the second narrow space 62. In the meantime, when the second distance W2 is too large, the light-emission distribution of the light-emitting mesa structure 22 becomes unbalanced. Accordingly, the second distance W2 is preferably equal to or more than 0.5 μm but equal to or less than 140 μm, more preferably equal to or more than 1 μm but equal to or less than 120 μm.

Since the first electrode area 31 directly receives a physical load at the time of external connection in comparison with the second electrode area 32, the first electrode area 31 is easily damaged and easily corrodes under a high humidity environment. However, since the first electrode area 31 and the second electrode area 32 are formed via the second distance W2, it is possible to restrain corrosion of the first electrode area 31 from spreading to the second electrode area 32 during current application under the a high humidity environment. The second electrode area 32 and the third electrode area 33 supply electrons (carriers) to the light-emitting mesa structure 22, and when spreading of corrosion to the second electrode area 32 is restrained, it is possible to restrain an increase in forward voltage or open mode failure in the nitride semiconductor light-emitting element 1 during current application under the highly humid environment.

### <Passivation Layer>

The passivation layer 50 includes the first passivation covering area 51 covering an edge (an outer edge of the protection mesa structure 23 which outer edge faces the first electrode area 31) that is part of the top surface of the protection mesa structure 23, the second passivation covering area 52 covering an outer edge of the first electrode area 31, and the third passivation covering area 53, which covers an outer edge of the second electrode area 32. That is, the passivation layer 50 is placed over the whole surface except the outer peripheral portion of the protection mesa structure 23 (the outer peripheral portion of the nitride semiconductor light-emitting element 1), the central portion of the first electrode 30 (the first electrode area 31, the second electrode area 32, and the third electrode area 33), and the central portion of the second electrode 40 and is also formed over the first narrow space 61 and the second narrow space 62.

When the first passivation covering area 51 covers the protection mesa structure 23, the adhesion of the passivation layer 50 to the protection mesa structure 23 improves, so that an area where the first n-type semiconductor layer 21 makes contact with air or moisture can be reduced. As an area where the first passivation covering area 51 covers the protection mesa structure 23 is larger, the adhesion of the passivation layer 50 to the protection mesa structure 23 more improves. Accordingly, when the first passivation covering area 51 covers the protection mesa structure 23, it is possible to achieve the nitride semiconductor light-emitting element 1 having a longer life. In the meantime, when the first passivation covering area 51 covers the whole protection mesa structure 23, the passivation layer 50 may crack at the time when the nitride semiconductor light-emitting element 1 on a wafer is separated into each piece. In view of this, it is preferable that the passivation layer 50 be placed to cover the outer edge of the protection mesa structure 23 which outer edge faces the first electrode area.

The passivation layer 50 includes the second passivation covering area 52 covering the outer edge of the first electrode area 31. That is, an end portion of the first electrode area 31 is held down by the second passivation covering area 52, thereby allowing the first electrode area 31 to have a high adhesion to the first n-type semiconductor layer 21. When an area where the second passivation covering area 52 covers the first electrode area 31 becomes large, the strength of the second passivation covering area 52 to hold down the first electrode area 31 increases. However, when the area where the second passivation covering area 52 covers the first electrode area 31 is too large, an opening on the first electrode area 31 becomes too small, which is unfavorable. By changing the size of the first electrode area 31, the second passivation covering area 52 can be enlarged with the size of the opening being maintained. However, when the second passivation covering area 52 is too large, the area of the whole chip becomes large and the output power per unit area of the chip decreases, which is unfavorable. In the meantime, when the area where the second passivation covering area 52 covers the first electrode area 31 is too small, the end portion of the first electrode area 31 cannot be covered by alignment at the time of manufacturing, which is unfavorable. On this account, the width with which the passivation layer 50 covers the end portion of the top surface of the first electrode area 31, that is, the width of an area of the top surface of the first electrode area 31 which area is covered with the second passivation covering area 52 (hereinafter, the width may be also referred to as the width of the second passivation covering area 52) is preferably equal to or more than 0.5 μm but equal to or less than 15 μm, more preferably equal to or more than 1 μm but equal to or less than 10 μm.

The passivation layer 50 includes the third passivation covering area 53 covering the outer edge of the second electrode area 32. That is, an end portion of the second electrode area 32 is held down by the third passivation covering area 53, thereby allowing the second electrode area 32 to have a high adhesion to the first n-type semiconductor layer 21. When an area where the third passivation covering area 53 covers the second electrode area 32 becomes larger, the strength of the third passivation covering area 53 to hold down the second electrode area 32 increases. However, when the area where the third passivation covering area 53 covers the second electrode area 32 is too large, an opening on the second electrode area 32 becomes too small, which is unfavorable. By changing the size of the second electrode area, the third passivation covering area can be enlarged with the size of the opening being maintained. However, when the third passivation covering area 53 is too large, the area of the whole chip becomes large and the output power per unit area of the chip decreases, which is unfavorable. In the meantime, when the area where the third passivation covering area 53 covers the second electrode area 32 is too small, the end portion of the second electrode area 32 cannot be covered by alignment at the time of manufacturing, which is unfavorable. On this account, the width with which the passivation layer 50 covers the end portion of the top surface of the second electrode area 32, that is, the width of an area of the top surface of the second electrode area 32 which area is covered with the third passivation covering area 53 (hereinafter, the width may be also referred to as the width of the third passivation covering area 53) is preferably equal to or more than 0.5 μm but equal to or less than 15 μm, more preferably equal to or more than 1 μm but equal to or less than 10 μm.

The passivation layer 50 is formed to overlap with the first narrow space 61 between the protection mesa structure 23 and the first electrode area 31 in the first n-type semiconductor layer 21 in a plan view. Hereby, the adhesion of the passivation layer 50 can be improved due to anchor effect. In this case, particularly, an effect that the first passivation covering area 51 adheres to the protection mesa structure 23 and an effect that the first electrode area 31 is held down by the second passivation covering area 52 are enhanced. The passivation layer 50 is formed to overlap with the second narrow space 62 between the first electrode area 31 and the second electrode area 32 in the first n-type semiconductor layer 21 in a plan view. Hereby, the adhesion of the passivation layer 50 can be improved due to anchor effect. In this case, particularly, an effect that the second passivation covering area 52 holds down the first electrode area 31 and an effect that the third passivation covering area 53 holds down the second electrode area 32 are enhanced. Thus, the passivation layer 50 is formed over the first narrow space 61 and the second narrow space 62, and therefore, even when the nitride semiconductor light-emitting element 1 receives a physical load at the time of external connection, it is possible to restrain peeling or cracks (including microcracks) of the passivation layer 50. Besides, the adhesion of the passivation layer 50 to the protection mesa structure 23 improves, so that the first n-type semiconductor layer 21 can hardly make contact with air or moisture, thereby achieving a long life of the nitride semiconductor light-emitting element 1.

In the nitride semiconductor light-emitting element 1 configured as such, it is possible to improve damage tolerance in the first electrode area 31 and the passivation layer 50 at the time when the nitride semiconductor light-emitting element 1 is externally connected. Accordingly, it is not necessary to set the areas of the first electrode area 31 and the opening provided on the first electrode area 31 to sizes including a large margin for sizes of electrically-conductive wires or conductive bumps to be bonded at the time of external connection. Hereby, it is not necessary to increase the area of the first electrode area 31 in the nitride semiconductor light-emitting element 1 more than required, thereby making it possible to increase the number of nitride semiconductor light-emitting elements 1 on a wafer surface. Besides, it is also possible to increase the area (the occupancy of the chip area) of the light-emitting mesa structure 22 in the nitride semiconductor light-emitting element 1. On this account, it is also possible to expect an effect of improving the output power per unit area in the nitride semiconductor light-emitting element 1.

The passivation layer 50 can be formed with the use of oxide or nitride such as SiN, SiO₂, SiON, Al₂O₃, and Zro layers, for example. From the viewpoint of water resistance and stress to a device, it is preferable that silicon oxide, silicon nitride, or both of them to be used for the passivation layer 50.

A method for forming the passivation layer 50 is not limited particularly, and the passivation layer 50 can be formed by a plasma CVD (Chemical Vapor Deposition) machine, a sputtering machine, a vapor deposition machine, and the like, for example. In a case where a silicon nitride film is formed as the passivation layer 50 by the plasma CVD machine, a method using mono-silane (SiH₄) as supply gas of silicon that is a structural element and ammonia (NH₃) as supply gas of nitrogen is widely known. In a case where a silicon oxide film is formed as the passivation layer 50 by the plasma CVD machine, a method using mono-silane (SiH₄) as supply gas of silicon that is a structural element and nitrous oxide (N₂O) as supply gas of oxygen is widely known.

From the viewpoint of productivity and stress to the device, the film thickness of the passivation layer 50 is preferably equal to or more than 10 nm but equal to or less than 1000 nm, and more preferably equal to or more than 50 nm but equal to or less than 500 nm.

From the viewpoint of further increasing water resistance and restraining peeling of the passivation layer 50, other passivation layers, a metal layer, and the like may be placed on the passivation layer 50.

### <Pad Electrode>

The pad electrode 70 is placed on a part of the passivation layer 50, the first electrode area 31, the second electrode area 32, and the third electrode area 33 not covered with the passivation layer 50, and the second electrode 40 not covered with the passivation layer 50. The pad electrode 70 includes the first pad electrode portion 71 electrically connecting the first electrode area 31, the second electrode area 32, and the third electrode area 33 to each other, the second pad electrode portion 72 placed on part of the passivation layer 50 and the second electrode 40 not covered with the passivation layer 50, and the third pad electrode portion 73 formed on a part of the passivation layer 50 and a part of the protection mesa structure 23.

The first pad electrode portion 71 covers a part of the second passivation covering area 52 and a part of the third passivation covering area 53. Accordingly, the first pad electrode portion 71 is effective to improve the adhesion of the second passivation covering area 52 to the first electrode area 31 and the adhesion of the third passivation covering area 53 to the second electrode area 32. By forming the first pad electrode portion 71, an external connection area based on the first electrode area 31, and a lead-out electrode area electrically connecting the first electrode area 31, the second electrode area 32, and the third electrode area 33 to each other can be formed at once, which is preferable from the viewpoint of simplification of the manufacturing process.

The second pad electrode portion 72 covers a part of a passivation covering area (not illustrated) where the passivation layer 50 covers the outer edge of the light-emitting mesa structure 22 (see FIG. 2A). Accordingly, the second pad electrode portion 72 is effective to improve the adhesion of the passivation layer 50 to the light-emitting mesa structure 22.

The third pad electrode portion 73 is provided to cover a part of the first passivation covering area 51, which covers the protection mesa structure 23. More specifically, as illustrated in FIG. 3, the third pad electrode portion 73 is placed to cover the first passivation covering area 51 as an area of the passivation layer 50 which area covers the outer edge of the protection mesa structure 23, and at least a part of an area of the protection mesa structure 23 which area is not covered by the passivation layer 50. Accordingly, the third pad electrode portion 73 is effective to improve the adhesion of the first passivation covering area 51 to the protection mesa structure 23.

Since the outer edge of the passivation layer 50 is covered with the pad electrode 70, it is possible to yield an effect of restraining water content from entering a semiconductor layer or an electrode portion from the end portion of the passivation layer 50 and restraining a reaction with oxygen or moisture in air, which is preferable from the viewpoint of reliability.

The following more specifically describes the invention of this disclosure with reference to examples and comparative examples. Note that the nitride semiconductor light-emitting element according to this disclosure is not limited to the following examples.

### EXAMPLES

### Example 1

### Example 1-1

A nitride semiconductor light-emitting element according to Example 1-1 is a nitride semiconductor light-emitting element having the structure illustrated in FIGS. 1, 2 in the embodiment. Each layer of the nitride semiconductor light-emitting element has the following structure.

The substrate is an AlN substrate.

The first n-type semiconductor layer is an n-type Al_{0.7}Ga_{0.3}N (n-Al_{0.7}Ga_{0.3}N) layer containing 2.0×10²⁰ cm⁻³ of Si as impurities, and the first n-type semiconductor layer has a thickness of 400 nm.

The light-emitting mesa structure is constituted by a second n-type semiconductor layer having a thickness of 150 nm, a first quantum well layer having a thickness of 70 nm, and a first p-type semiconductor layer having a thickness of 10 nm. The protection mesa structure is constituted by a third n-type semiconductor layer having a thickness of 150 nm, a second quantum well layer having a thickness of 70 nm, and a second p-type semiconductor layer having a thickness of 10 nm.

The second n-type semiconductor layer and the third n-type semiconductor layer are each made of an n-Al_{0.7}Ga_{0.3}N layer containing 2.0×10²⁰ cm⁻³ of Si as impurities. The first quantum well layer and the second quantum well layer are each formed such that five Al_{0.51}Ga_{0.49}N layers (well layers) each having a thickness of 3 nm and five Al_{0.78}Ga_{0.22}N layers (barrier layers) each having a thickness of 11 nm and containing Si as impurities are alternately laminated. The first p-type semiconductor layer of the light-emitting mesa structure and the second p-type semiconductor layer of the protection mesa structure are each made of a p-type GaN (p-GaN) layer containing 2.0×10²⁰ cm⁻³ of Mg as impurities.

A first electrode formed on the first n-type semiconductor layer is constituted by Ti, Al, Ni, and Au.

A second electrode formed on the first p-type semiconductor layer of the light-emitting mesa structure is constituted by Ni and Au.

A passivation layer is a silicon nitride layer and has a membrane thickness of 240 nm.

The nitride semiconductor light-emitting element of Example 1-1 was manufactured by the following method.

First, an n-Al_{0.7}Ga_{0.3}N layer containing 2.0×10²⁰ cm⁻³ of Si as impurities was formed with a thickness of 550 nm on an AlN substrate made of an AlN single crystal.

Then, five Al_{0.51}Ga_{0.49}N layers each having a thickness of 3 nm and five Al_{0.78}Ga_{0.22}N layers each having a thickness of 11 nm and containing Si as impurities were alternately laminated on the n-Al_{0.7}Ga_{0.3}N layer so that a total thickness was 70 nm.

Subsequently, a p-GaN layer containing 2.0×10²⁰ cm⁻³ of Mg as impurities was formed with a thickness of 10 nm. These layers were formed by the metal organic chemical vapor deposition method (MOCVD method).

Thus, a laminate made of nitride semiconductor layers was formed on the AlN substrate.

Subsequently, the laminate on the AlN substrate was subjected to dry etching to remove, by a predetermined depth, an area of the laminate other than an area to become a light-emitting mesa structure and an area to become a protection mesa structure, so that part of the n-Al_{0.7}Ga_{0.3}N layer was exposed. Hereby, the laminate was formed in such a shape that the light-emitting mesa structure and the protection mesa structure projected from the first n-type semiconductor layer having a thickness of 400 nm. The dry etching was performed with the use of chlorine-based gas after a resist pattern was formed on the laminate by the photolithography method. A chip in Example 1 had a square shape with a chip size of 860 μm per side, and the protection mesa structure was formed in an inward area with 20 μm in width from the outer periphery of the chip.

Subsequently, a Ti layer, an Al layer, an Ni layer, and an Au layer were sequentially formed on a part of the first n-type semiconductor layer thus exposed, by an electron beam evaporation method, so as to form a metal laminated film, and the metal laminated film was subjected to heat-treating by the RTA method to form a first electrode. At this time, the first electrode (a first electrode area, a second electrode area, and a third electrode area) was formed so that a first distance as a distance between the protection mesa structure and the first electrode area was 2 μm, and a second distance as a distance between the first electrode area and the second electrode area was 9 μm.

Further, an Ni layer and an Au layer were sequentially formed on part of the first p-type semiconductor layer of the light-emitting mesa structure by the electron beam evaporation method to form a metal laminated film, and the metal laminated film was subjected to heat-treating by the RTA method to form a second electrode.

Subsequently, a silicon nitride film having a thickness of 240 nm was formed by the plasma-CVD method to cover the whole AlN substrate (the whole top surface and lateral surface) on which the light-emitting mesa structure, the protection mesa structure, the first electrode, and the second electrode were formed.

Subsequently, an opening was formed at a predetermined position on the silicon nitride film by etching by CF₄ with the use of a resist pattern formed by the photolithography method. In Example 1-1, the opening was formed on a part of the top surface of the first electrode and a part of the top surface of the second electrode. At this time, the opening was formed such that a first passivation covering area, which covers a part of the top surface of the protection mesa structure had a width of 7 μm, a second passivation covering area, which covers an outer edge of the first electrode area had a width of 4 μm, and a third passivation covering area, which covers an outer edge of the second electrode area had a width of 4 μm. Subsequently, a first pad electrode was formed on the first electrode inside the opening thus formed, in such a manner that Ti was deposited to have a thickness of 20 nm and Au was then deposited to have a thickness of 1000 nm. Further, a second pad electrode was formed on the second electrode inside the opening thus formed, in such a manner that Ti was deposited to have a thickness of 20 nm and Au was then deposited to have a thickness of 1000 nm.

Subsequently, a back surface side of the AlN substrate was subjected to grinding until the AlN substrate had a thickness of 100 μm. Note that those steps were performed in wafer state.

Finally, this wafer was separated into pieces by laser dicing and breaking, and a submount was packaged by flip chip bonding by a GGI (Gold to Gold Interconnection) method.

### [Evaluation]

In order to check an effect of damage tolerance in external connection in terms of the nitride semiconductor light-emitting element of Example 1-1, peeling status of the first pad electrode and the first electrode (the first electrode area) were observed. It was found that no peeling occurred in the nitride semiconductor light-emitting element of Example 1-1. Note that, since the nitride semiconductor light-emitting element after grinding had a sufficient transparency, the peeling status of the pad electrode and the first electrode in an external connection area can be visually observed from the backside.

Furthermore, in order to evaluate invisible peeling, breakage, and microcracks of the first pad electrode or the first electrode, a 1000-hour continuous-current test (250 mA) was performed on the nitride semiconductor light-emitting element under an environment with 55° C. and an RH of 85%. Generally, when the nitride semiconductor or the first electrode (an n-type semiconductor electrode) containing Al deteriorates due to reaction with oxygen or moisture in air under current test, the nitride semiconductor or the first electrode shows black discoloration, and when the deterioration further advances, the semiconductor increases resistance, and an increase in forward voltage of an element is observed. In view of this, when the appearance around the external connection area after the continuous-current test was evaluated, it was found that no black discoloration occurred around the external connection area. That is, in the nitride semiconductor light-emitting element of Example 1-1, it was found that peeling or breakage of the pad electrode or the first electrode and peeling and cracks (microcracks) of the passivation layer due to a physical load in external connection were restrained. That is, in Example 1-1, it was confirmed that the nitride semiconductor light-emitting element improved in damage tolerance in external connection was achieved.

### Comparative Example 1-1

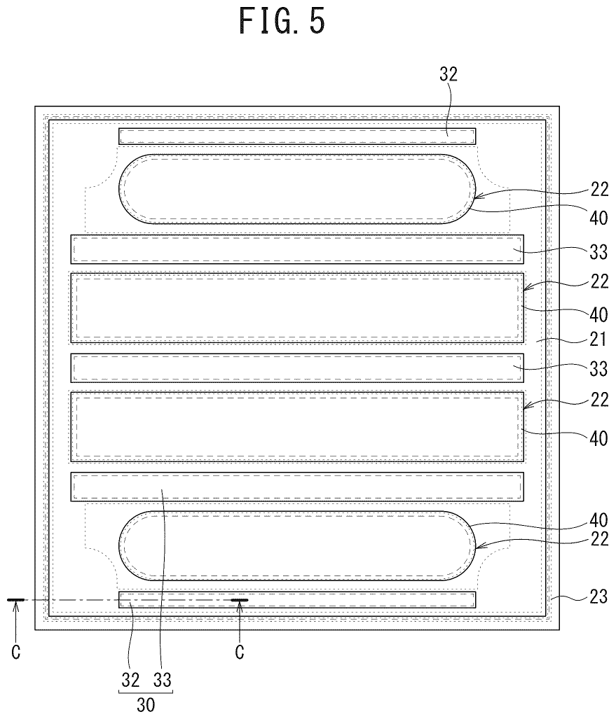

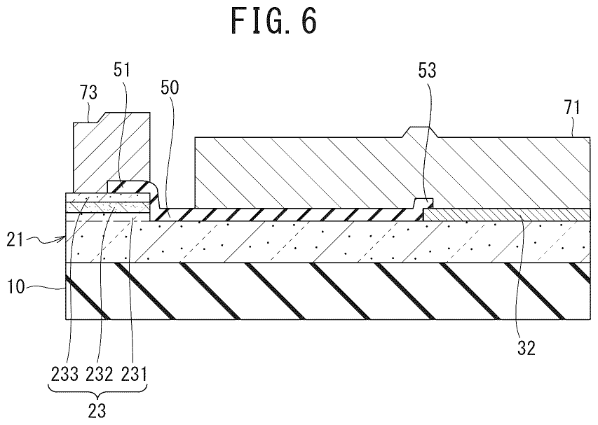

A nitride semiconductor light-emitting element according to Comparative Example 1-1 is a nitride semiconductor light-emitting element having a structure illustrated in FIGS. 5, 6. Here, FIG. 5 is a plan schematic view illustrating a schematic structure of the nitride semiconductor light-emitting element according to Comparative Example 1-1, and FIG. 6 is a cross sectional schematic view illustrating a schematic structure of the nitride semiconductor light-emitting element and illustrates a section C-C in FIG. 5. Note that, in FIGS. 5, 6, a portion corresponding to a portion constituting the nitride semiconductor light-emitting element illustrated in FIGS. 1, 2 has the same reference sign as in FIGS. 1, 2, for facilitation of description.

In Comparative Example 1-1, the nitride semiconductor light-emitting element was formed in a similar manner to Example 1-1 except that only the second electrode area and the third electrode area were formed without the first electrode area at the time when a metal laminated film to become the first electrode was formed, and no opening was formed in an area where the first electrode area was not formed, at the time when the opening was formed by performing CF₄-etching on silicon nitride.

### [Evaluation]

In terms of the nitride semiconductor light-emitting element of Comparative Example 1-1, the peeling status of the first pad electrode of an area (the area where the first electrode area was not formed) similar to a corresponding area in Example 1-1 was observed by a method similar to the method in Example 1-1. As a result, peeling was clearly observed in the first pad electrode portion. Since the first electrode area was not formed in Comparative Example 1-1, the first narrow space between the protection mesa structure and the first electrode area and the second narrow space between the first electrode area and the second electrode area cannot be formed. That is, the area where the first electrode area was not formed needs to endure physical damage only by adhesion between the first pad electrode and the passivation layer, and it is considered that the adhesion between the first pad electrode and the passivation layer was insufficient.

### Comparative Example 1-2

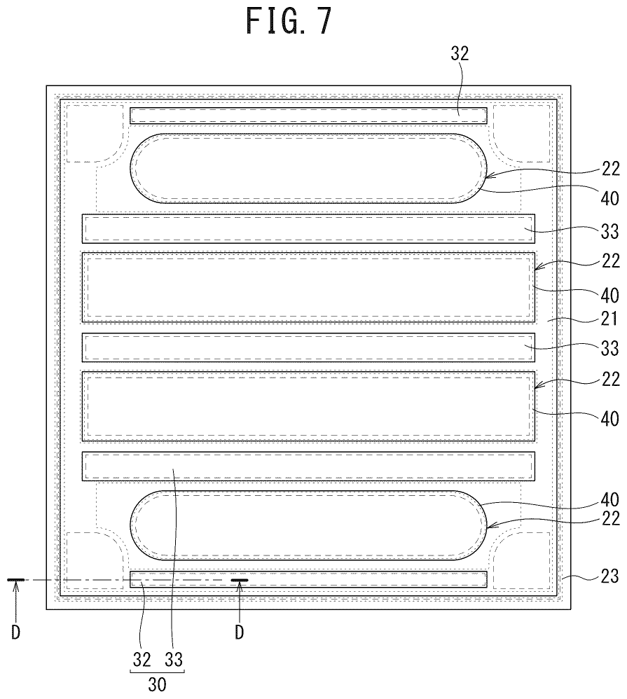

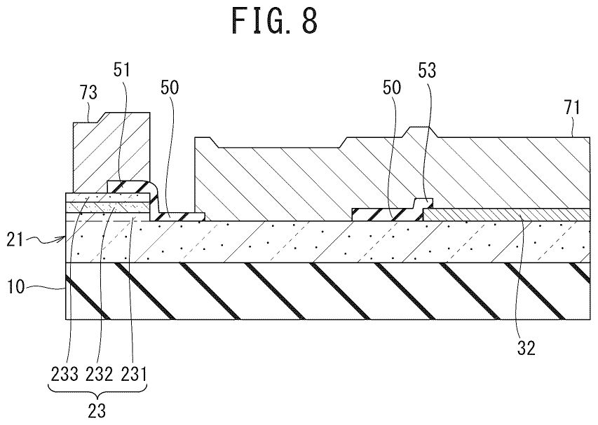

A nitride semiconductor light-emitting element according to Example 1-2 is a nitride semiconductor light-emitting element having a structure illustrated in FIGS. 7, 8. Here, FIG. 7 is a plan schematic view illustrating a schematic structure of the nitride semiconductor light-emitting element according to Comparative Example 1-2, and FIG. 8 is a cross sectional schematic view illustrating a schematic structure of the nitride semiconductor light-emitting element and illustrates a section D-D in FIG. 7. Note that, in FIGS. 7, 8, a portion corresponding to a portion constituting the nitride semiconductor light-emitting element illustrated in FIGS. 1, 2 has the same reference sign as in FIGS. 1, 2, for facilitation of description.

In Comparative Example 1-2, the nitride semiconductor light-emitting element was formed in a similar manner to Example 1-1 except that only the second electrode area and the third electrode area were formed without the first electrode area at the time when a metal laminated film as the first electrode was formed, and an opening was formed in an area where the first electrode area was not formed, at the time when the opening was formed by performing CF₄-etching on silicon nitride.

### [Evaluation]

In terms of the nitride semiconductor light-emitting element of Comparative Example 1-2, the peeling status of the first pad electrode of an area (the area where the first electrode area was not formed) similar to a corresponding area in Example 1-1 was observed by a method similar to the method in Example 1-1. As a result, peeling was clearly observed in the first pad electrode portion, although the peeling status was improved as compared with Comparative Example 1-1. Since the first electrode area was not formed in Comparative Example 1-2, similarly to Comparative Example 1-1, the first narrow space and the second narrow space could not be formed. That is, it is considered that, in the area where the first electrode area was not formed in Comparative Example 1-2, the adhesion between the first pad electrode and the first n-type semiconductor layer was improved as compared to the adhesion between the first pad electrode and the passivation layer in the area where the first electrode area was not formed in Comparative Example 1-1, but the adhesion was insufficient.

Evaluation results in Example 1 are shown in Table 1 as follows.

TABLE 1

| | | | | | | | Width of | | |
|---|---|---|---|---|---|---|---|---|---|
| | | | | | First | Second | second | Evaluation | |
| | Structure | First | Second | | distance | distance | passivation | Detachment | Blackening |
| | of external | electrode | electrode | Narrow | W1 | W2 | covering area | before | after |
| | connection area | area | area | space | [μm] | [μm] | [μm] | current test | current test |
| Ex. 1-1 | FIG. 1, FIG. 2B | Yes | Yes | Yes | 2 | 9 | 4 | No | No |
| Comp. | FIG. 5, FIG. 6 | No | Yes | No | — | — | — | Yes | — |
| Ex. 1-1 | | | | | | | | | |
| Comp. | FIG. 7, FIG. 8 | No | Yes | No | — | — | — | Yes | — |
| Ex. 1-2 | | | | | | | | | |

Thus, it is found that the structure of Example 1-1 can achieve a nitride semiconductor light-emitting element improved in damage tolerance in external connection.

### Example 2

In Example 2, nitride semiconductor light-emitting elements of Example 2-1 to 2-9 manufactured to include respective second passivation covering areas different in width were evaluated. More specifically, the first electrode was formed while the size of the first electrode area in a photo mask to form the first electrode was changed so that change the length of the second passivation covering portion was changed. Here, since the opening size of the passivation layer was maintained, an alignment margin to a conductive bump (see FIG. 2B) for external connection was maintained, so that evaluation was performed with a structure to which an equivalent physical load was applied. It was necessary to increase a chip size due to an increase in size of the first electrode area, and therefore, the nitride semiconductor light-emitting element was manufactured such that other photo masks were modified to be suited to the first electrode, including the pitch of one chip. In a case where the size of the first electrode area was decreased, the chip size was not changed. Nitride semiconductor light-emitting elements of Examples and Comparative Examples were manufactured in a similar manner to Example 1-1, except that photo masks to be used were changed.

### Example 2-1

The nitride semiconductor light-emitting element of Example 2-1 was formed in a similar manner to Example 1-1 except that the second passivation covering area had a width of 0.1 μm.

### Example 2-2

The nitride semiconductor light-emitting element of Example 2-2 was formed in a similar manner to Example 1-1 except that the second passivation covering area had a width of 0.5 μm.

### Example 2-3

The nitride semiconductor light-emitting element of Example 2-3 was formed in a similar manner to Example 1-1 except that the second passivation covering area had a width of 1.0 μm.

### Example 2-4

The nitride semiconductor light-emitting element of Example 2-4 was formed in a similar manner to Example 1-1 except that the second passivation covering area had a width of 2.0 μm.

### Example 2-5

The nitride semiconductor light-emitting element of Example 2-5 was formed in a similar manner to Example 1-1 except that the second passivation covering area had a width of 8.0 μm.

### Example 2-6

The nitride semiconductor light-emitting element of Example 2-6 was formed in a similar manner to Example 1-1 except that the second passivation covering area had a width of 10 μm.

### Example 2-7

The nitride semiconductor light-emitting element of Example 2-7 was formed in a similar manner to Example 1-1 except that the second passivation covering area had a width of 15 μm.

### Example 2-8

The nitride semiconductor light-emitting element of Example 2-8 was formed in a similar manner to Example 1-1 except that the second passivation covering area had a width of 17 μm.

### Example 2-9

The nitride semiconductor light-emitting element of Example 2-9 was formed in a similar manner to Example 1-1 except that the second passivation covering area had a width of 20 μm.

### [Evaluation]

In terms of the nitride semiconductor light-emitting element of each example, the peeling status of the first pad electrode and the first electrode (particularly, the first electrode area) and discoloration after the continuous-current test were observed by a method similar to the method in Example 1-1.

In addition, in terms of the nitride semiconductor light-emitting element of each example, evaluation was performed such that an output power at the time of application of 500 mA was measured, and a relative output per unit area of a chip was calculated with the nitride semiconductor light-emitting element of Example 1-1 being taken as a reference (1.00).

Evaluation results in Example 2 are shown in Table 2 as follows.

TABLE 2

| | | | | | | | Width of | | | |
|---|---|---|---|---|---|---|---|---|---|---|
| | | | | | First | Second | second | Evaluation | | |
| | Structure | First | Second | | distance | distance | passivation | Detachment | Blackening | Relative |
| | of external | electrode | electrode | Narrow | W1 | W2 | covering area | before | after | output per |
| | connection area | area | area | space | [μm] | [μm] | [μm] | current test | current test | unit area |
| Ex. 1-1 | FIG. 1, FIG. 2B | Yes | Yes | Yes | 2 | 9 | 4 | No | No | 1.00 |
| Ex. 2-1 | | | | | | | 0.1 | No | Yes | 1.00 |
| Ex. 2-2 | | | | | | | 0.5 | No | No | 1.00 |
| Ex. 2-3 | | | | | | | 1 | No | No | 1.00 |
| Ex. 2-4 | | | | | | | 2 | No | No | 1.00 |
| Ex. 2-5 | | | | | | | 8 | No | No | 0.96 |
| Ex. 2-6 | | | | | | | 10 | No | No | 0.95 |
| Ex. 2-7 | | | | | | | 15 | No | No | 0.91 |
| Ex. 2-8 | | | | | | | 17 | No | No | 0.89 |
| Ex. 2-9 | | | | | | | 20 | No | No | 0.87 |

As shown in Table 2, in the nitride semiconductor light-emitting element of each example, no peeling occurred in the first pad electrode or the first electrode area regardless of the width of the second passivation covering area. It was found that the nitride semiconductor light-emitting elements of Example 2-2 to 2-9 in each of which the second passivation covering area had a width equal to or more than 0.5 μm had an additional effect that black discoloration of the nitride semiconductor or the first electrode was restrained, that is, invisible peeling, breakage, and microcracks of the first pad electrode or the first electrode were restrained, in addition to no peeling of the first pad electrode or the first electrode area. It is considered that, in a case where the second passivation covering area had a width equal to or more than 0.5 μm, the first electrode area was sufficiently covered with the passivation layer, so that invisible peeling, breakage, and microcracks of the first pad electrode or the first electrode were restrained. In consideration of a margin for alignment of a photo mask, the width of the second passivation covering area is preferably equal to or more than 1 μm.

As shown in Table 2, as the width of the second passivation covering area was narrower, the relative output power per unit area of the chip tended to gradually improve. It is considered that, as the width of the second passivation covering area is narrower, the chip size is smaller, so that the output per unit area of the chip improves. In view of this, the width of the second passivation covering area is preferably equal to or less than 15 μm, more preferably 10 μm.

Thus, it is found that the width of the second passivation covering area is preferably equal to or more than 0.5 μm but equal to or less than 15 μm, more preferably equal to or more than 1 μm but equal to or less than 10 μm.

### Example 3

In Example 3, nitride semiconductor light-emitting elements of Examples 3-1 to 3-8 each of which was manufactured by changing the first distance between the protection mesa structure and the first electrode area were evaluated. More specifically, the position of the protection mesa structure was changed on a photo mask to form a mesa structure, so as to change the distance between the protection mesa structure and the first electrode area. Since the chip size was changed due to the change in the design of the photo mask, the nitride semiconductor light-emitting element was manufactured such that other photo masks were modified to be suited to the protection mesa structure, including the pitch of one chip. Nitride semiconductor light-emitting elements of Examples and Comparative Examples were manufactured in a similar manner to Example 1-1, except that photo masks to be used were changed.

### Example 3-1

The nitride semiconductor light-emitting element of Example 3-1 was formed in a similar manner to Example 1-1 except that the first distance was 0.1 μm.

### Example 3-2

The nitride semiconductor light-emitting element of Example 3-2 was formed in a similar manner to Example 1-1 except that the first distance was 0.5 μm.

### Example 3-3

The nitride semiconductor light-emitting element of Example 3-3 was formed in a similar manner to Example 1-1 except that the first distance was 1 μm.

### Example 3-4

The nitride semiconductor light-emitting element of Example 3-4 was formed in a similar manner to Example 1-1 except that the first distance was 10 μm.

### Example 3-5

The nitride semiconductor light-emitting element of Example 3-5 was formed in a similar manner to Example 1-1 except that the first distance was 15 μm.

### Example 3-6

The nitride semiconductor light-emitting element of Example 3-6 was formed in a similar manner to Example 1-1 except that the first distance was 20 μm.

### Example 3-7

The nitride semiconductor light-emitting element of Example 3-7 was formed in a similar manner to Example 1-1 except that the first distance was 25 μm.

### Example 3-8

The nitride semiconductor light-emitting element of Example 3-8 was formed in a similar manner to Example 1-1 except that the first distance was 30 μm.

### [Evaluation]

In terms of the nitride semiconductor light-emitting element of each example, the peeling status of the first pad electrode and the first electrode (particularly, the first electrode area) and discoloration after the continuous-current test were observed by a method similar to the method in Example 1-1.

In addition, in terms of the nitride semiconductor light-emitting element of each example, evaluation was performed such that an output power at the time of application of 500 mA was measured, and a relative output per unit area of a chip was calculated with the nitride semiconductor light-emitting element of Example 1-1 being taken as a reference (1.00).

Evaluation results in Example 3 are shown in Table 3 as follows.

TABLE 3

| | | | | | | | Width of | | | |
|---|---|---|---|---|---|---|---|---|---|---|
| | | | | | First | Second | second | Evaluation | | |
| | Structure of | First | Second | | distance | distance | passivation | Detachment | Blackening | Relative |
| | external | electrode | electrode | Narrow | W1 | W2 | covering area | before | after | output per |
| | connection area | area | area | space | [μm] | [μm] | [μm] | current test | current test | unit area |
| Ex. 1-1 | FIG. 1, FIG. 2B | Yes | Yes | Yes | 2 | 9 | 4 | No | No | 1.00 |
| Ex. 3-1 | | | | | 0.1 | | | No | Yes | 1.00 |
| Ex. 3-2 | | | | | 0.5 | | | No | No | 1.00 |
| Ex. 3-3 | | | | | 1 | | | No | No | 1.00 |
| Ex. 3-4 | | | | | 10 | | | No | No | 0.96 |
| Ex. 3-5 | | | | | 15 | | | No | No | 0.94 |
| Ex. 3-6 | | | | | 20 | | | No | No | 0.92 |
| Ex. 3-7 | | | | | 25 | | | No | No | 0.90 |
| Ex. 3-8 | | | | | 30 | | | No | No | 0.88 |

As shown in Table 3, in the nitride semiconductor light-emitting element of each example, no peeling occurred in the first pad electrode or the first electrode area regardless of the first distance between the protection mesa structure and the first electrode area. It was found that the nitride semiconductor light-emitting elements of Example 3-2 to 3-8 in each of which the first distance was equal to or more than 0.5 μm had an additional effect that black discoloration of the nitride semiconductor or the first electrode was restrained, that is, invisible peeling, breakage, and microcracks of the first pad electrode and the first electrode were restrained, in addition to no peeling of the first pad electrode or the first electrode area. It was found that, in a case where the first distance was equal to or more than 0.5 μm, no interference color was observed in the first space, and excellent coverage of the passivation layer was achieved. Accordingly, the first distance is preferably equal to or more than 0.5 μm, more preferably equal to or more than 1 μm.

As shown in Table 3, as the first distance was shorter, the relative output power per unit area of the chip tended to gradually improve. It is considered that, as the first distance is narrower, the size of the whole chip becomes smaller, that is, the area ratio of the light-emitting mesa structure becomes larger, so that the relative output power per unit area of the chip tends to gradually improve. Accordingly, the first distance is preferably equal to or less than 25 μm, more preferably equal to or less than 20 μm.

Thus, it is found that the distance of the first narrow space is preferably equal to or more than 0.5 μm but equal to or less than 25 μm, more preferably equal to or more than 1 μm but equal to or less than 20 μm.

### Example 4

In Example 4, nitride semiconductor light-emitting elements of Example 4-1 to 4-7 each of which was manufactured by changing the second distance between the first electrode area and the second electrode area were evaluated. More specifically, the length of the second electrode area was changed on a photo mask to form the first electrode area, so as to change the distance between the first electrode area and the second electrode area. Nitride semiconductor light-emitting elements of Examples and Comparative Examples were manufactured in a similar manner to Example 1-1, except that photo mask for the second electrode area and a mask for passivation opening were changed.

### Example 4-1

The nitride semiconductor light-emitting element of Example 4-1 was formed in a similar manner to Example 1-1 except that the second distance was 0.1 μm.

### Example 4-2

The nitride semiconductor light-emitting element of Example 4-2 was formed in a similar manner to Example 1-1 except that the second distance was 0.5 μm.

### Example 4-3

The nitride semiconductor light-emitting element of Example 4-3 was formed in a similar manner as Example 1-1 except that the second distance was 1 μm.

### Example 4-4

The nitride semiconductor light-emitting element of Example 4-4 was formed in a similar manner to Example 1-1 except that the second distance was 100 μm.

### Example 4-5

The nitride semiconductor light-emitting element of Example 4-5 was formed in a similar manner to Example 1-1 except that the second distance was 120 μm.

### Example 4-6

The nitride semiconductor light-emitting element of Example 4-6 was formed in a similar manner to Example 1-1 except that the second distance was 140 μm.

### Example 4-7

The nitride semiconductor light-emitting element of Example 4-7 was formed in a similar manner to Example 1-1 except that the second distance was 160 μm.

### [Evaluation]

In terms of the nitride semiconductor light-emitting element of each example, the peeling status of the first pad electrode and the first electrode (particularly, the first electrode area) and discoloration after the continuous-current test were observed by a method similar to the method in Example 1-1.

In terms of the nitride semiconductor light-emitting element of each example, evaluation was performed such that the area of a light emitting area (an area that emitted light by 85% or more of emission maximum strength) on a surface of a chip at the time of application of 500 mA was measured, and the area of the light emitting area was calculated as a relative output power per unit area of the chip with the area of the light emitting area in the nitride semiconductor light-emitting element of Example 1-1 being taken as a reference (1.00).

Evaluation results in Example 4 are shown in Table 4 as follows.

TABLE 4

| | | | | | | | Width of | | | |
|---|---|---|---|---|---|---|---|---|---|---|
| | | | | | First | Second | second | Evaluation | | |
| | Structure of | First | Second | | distance | distance | passivation | Detachment | Blackening | Relative |
| | external | electrode | electrode | Narrow | W1 | W2 | covering area | before | after | output per |
| | connection area | area | area | space | [μm] | [μm] | [μm] | current test | current test | unit area |
| Ex. 1-1 | FIG. 1, FIG. 2B | Yes | Yes | Yes | 2 | 9 | 4 | No | No | 1.00 |
| Ex. 4-1 | | | | | | 0.1 | | No | Yes | 1.00 |
| Ex. 4-2 | | | | | | 0.5 | | No | No | 1.00 |
| Ex. 4-3 | | | | | | 1 | | No | No | 1.00 |
| Ex. 4-4 | | | | | | 100 | | No | No | 1.00 |
| Ex. 4-5 | | | | | | 120 | | No | No | 0.96 |
| Ex. 4-6 | | | | | | 140 | | No | No | 0.92 |
| Ex. 4-7 | | | | | | 160 | | No | No | 0.88 |

As shown in Table 4, in the nitride semiconductor light-emitting element of each example, no peeling occurred in the first pad electrode or the first electrode area regardless of the second distance between the first electrode area and the second electrode area. It was found that the nitride semiconductor light-emitting elements of Example 4-2 to 4-7 in each of which the second distance was equal to or more than 0.5 μm had an additional effect that black discoloration of the nitride semiconductor or the first electrode was restrained, that is, invisible peeling, breakage, and microcracks of the first pad electrode or the first electrode were restrained, in addition to no peeling of the first pad electrode or the first electrode area. It was found that, in a case where the second distance was equal to or more than 0.5 μm, no interference color was observed in the second space, and excellent coverage of the passivation layer was achieved. Accordingly, the second distance is preferably equal to or more than 0.5 μm, more preferably equal to or more than 1 μm.

As shown in Table 4, as the second distance was shorter, the relative output power per unit area of the chip tended to gradually improve. As the second distance becomes shorter, the length of the electrode becomes longer, so that electrons are easily supplied to the distal end of the light-emitting mesa structure, and hereby, unevenness can hardly occur in a light emitting area. Thus, as the second distance is shorter, the length of the second electrode can be maintained long, and hereby, unevenness can hardly occur in the light emitting area. Since unevenness can hardly occur in the light emitting area, a partial decrease in light output can hardly occur, thereby improving light output per unit area of the chip. On this account, the second distance is preferably equal to or less than 140 μm, more preferably equal to or less than 120 μm.

In view of this, the distance of the second distance is preferably equal to or more than 0.5 μm but equal to or less than 140 μm, more preferably equal to or more than 1 μm but equal to or less than 120 μm.

The embodiment of this disclosure has been described above, but the technical scope of this disclosure is not limited to the technical scope as claimed in the above embodiment. The above embodiment can be variously modified or altered, and it is apparent from the description of Claims that the technical scope of this disclosure can also include an embodiment including such a modification or alteration.

### REFERENCE SIGNS LIST

1: nitride semiconductor light-emitting element
10: substrate
20: nitride semiconductor laminate
21: first n-type semiconductor layer
22: light-emitting mesa structure
221: second n-type semiconductor layer
222: first quantum well layer
223: first p-type semiconductor layer
23: protection mesa structure
231: third n-type semiconductor layer
232: second quantum well layer
233: second p-type semiconductor layer
30: first electrode
31: first electrode area
32: second electrode area
33: third electrode area
40: second electrode
50: passivation layer
51: first passivation covering area
52: second passivation covering area
53: third passivation covering area
60: narrow space
61: first narrow space
62: second narrow space
70: pad electrode
71: first pad electrode portion
72: second pad electrode portion
73: third pad electrode portion

1. A nitride semiconductor light-emitting element, comprising:
a substrate;
a nitride semiconductor laminate including
a first conductivity type semiconductor layer placed on the substrate,
a light-emitting mesa structure placed on part of the first conductivity type semiconductor layer, and
a protection mesa structure placed on the first conductivity type semiconductor layer and spatially separated from the light-emitting mesa structure to surround the light-emitting mesa structure, the protection mesa structure emitting no light;
a first electrode placed on another part of the first conductivity type semiconductor layer and including at least two or more electrode areas including a first electrode area placed away from the protection mesa structure via a first distance in a plan view and a second electrode area placed away from the first electrode area via a second distance;
a passivation layer directly covering respective surfaces of an edge of the protection mesa structure, outer edges of each of a plurality of electrode areas, and the first conductivity type semiconductor layer; and
a first pad electrode placed to cover a surface of part of the passivation layer and a surface of at least part of an area of each of the plurality of electrode areas which area is not covered with the passivation layer, the first pad electrode being configured to electrically connect the plurality of electrode areas to each other.

2. The nitride semiconductor light-emitting element according to claim 1, wherein
the protection mesa structure is placed on an outer edge of the substrate.

3. The nitride semiconductor light-emitting element according to claim 2, wherein
the first electrode area includes a plurality of first electrode areas placed at two or more corners of the substrate in a plan view such that the plurality of first electrode areas is away from the protection mesa structure by the first distance.

4. The nitride semiconductor light-emitting element according to claim 2, wherein
the first electrode area includes a plurality of first electrode areas placed at four corners of the substrate in a plan view such that the plurality of first electrode areas is away from the protection mesa structure by the first distance.

5. The nitride semiconductor light-emitting element according to claim 1, wherein
the light-emitting mesa structure and the protection mesa structure are placed in an area other than a first narrow space formed to have the first distance between the protection mesa structure and the first electrode area, and a second narrow space formed to have a second distance between the first electrode area and the second electrode area.

6. The nitride semiconductor light-emitting element according to claim 1, wherein
the passivation layer includes a first passivation covering area covering an edge of the protection mesa structure which edge faces the first electrode area.

7. The nitride semiconductor light-emitting element according to claim 6, wherein
the passivation layer is formed to overlap, in a plan view, with at least part of an area of the first conductivity type semiconductor layer which area is between the protection mesa structure and the first electrode area, and at least part of an area of the first conductivity type semiconductor layer which area is between the first electrode area and the second electrode area.

8. The nitride semiconductor light-emitting element according to claim 1, wherein
the passivation layer has a second passivation covering area covering an edge of the first electrode area, and
an area where a top surface of the first electrode area is covered with the second passivation covering area has a width equal to or more than 0.5 μm but equal to or less than 15 μm.

9. The nitride semiconductor light-emitting element according to claim 8, wherein
the first pad electrode is provided to cover part of the second passivation covering area.

10. The nitride semiconductor light-emitting element according to claim 1, further comprising:
a third pad electrode portion placed to cover an area of the passivation layer which area covers the edge of the protection mesa structure, and at least part of an area of the protection mesa structure which area is not covered with the passivation layer.

11. The nitride semiconductor light-emitting element according to claim 1, wherein
the first distance is equal to or more than 0.5 μm but equal to or less than 25 μm.

12. The nitride semiconductor light-emitting element according to claim 1, wherein
the second distance as a distance between the first electrode area and the second electrode area is equal to or more than 0.5 μm but equal to or less than 140 μm.

13. The nitride semiconductor light-emitting element according to claim 1, wherein
the protection mesa structure is placed to surround the light-emitting mesa structure in a plan view.

14. The nitride semiconductor light-emitting element according to claim 1, wherein:
the substrate has a rectangular shape in a plan view;
the protection mesa structure is provided along an outer periphery of the substrate;
the light-emitting mesa structure includes a plurality of light-emitting mesa structure along the same direction as a direction of one side of the protection mesa structure;
the first electrode area is provided inward of a corner of the protection mesa structure; and
the second electrode area is provided to be adjacent to the first electrode area and extend in one direction along the protection mesa structure and the light-emitting mesa structure.
